(19) United States
(12) Patent Application Publication
(10) Pub. No.: US 2023/0124120 A1
(43) Pub. Date: Apr. 20, 2023

(54) SYSTEM AND METHOD FOR EVALUATING BOTTOM HOLE ASSEMBLIES

(71) Applicant: Schlumberger Technology Corporation, Sugar Land, TX (US)

(72) Inventors: Yingwei Yu, Katy, TX (US); Cheolkyun Jeong, Katy, TX (US); Yuelin Shen, Katy, TX (US); Wei Chen, Katy, TX (US); Zhengxin Zhang, Katy, TX (US); Velizar Vesselinov, Katy, TX (US)

(21) Appl. No.: 17/449,399

(22) Filed: Sep. 29, 2021

(51) Int. Cl. E21B 44/00; E21B 49/00; G06F 30/20

(52) U.S. Cl. CPC E21B 44/00; E21B 49/00; G06F 30/20; E21B 2200/20

(57) ABSTRACT

A method for evaluating one or more bottom hole assemblies (BHAs) includes receiving a plurality of inputs. The inputs include one or more properties of the one or more BHAs, a planned trajectory of a wellbore, and one or more properties of a subterranean formation into which the wellbore will be drilled. The method also includes simulating drilling the wellbore in the subterranean formation based at least partially upon the inputs. Drilling of the wellbore is simulated with one or more artificial intelligence (AI) agents. Drilling of the wellbore is simulated a plurality of times using each of the one or more BHAs, thereby producing a plurality of simulations. Each simulation is generated using a different one of the AI agents. The method also includes generating one or more outputs in response to simulating drilling the wellbore.

### BACKGROUND

Wellbores are generally drilled into the earth along a planned trajectory using a bottom hole assembly (BHA) at the lower end of a drill string. Oftentimes, multiple different BHAs may be available, and each BHA may drill the wellbore differently than the other BHAs. A user (e.g., a directional driller or DD) at the wellsite is tasked with selecting one of the BHAs to drill the particular wellbore. However, there are many factors that may be considered when selecting a BHA, and the analysis may be complicated and time-consuming. Therefore, what is needed is a system and method for evaluating BHAs in a simulated environment.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

A method for evaluating one or more bottom hole assemblies (BHAs) is disclosed. The method includes receiving a plurality of inputs. The inputs include one or more properties of the one or more BHAs, a planned trajectory of a wellbore, and one or more properties of a subterranean formation into which the wellbore will be drilled. The method also includes simulating drilling the wellbore in the subterranean formation based at least partially upon the inputs. Drilling of the wellbore is simulated with one or more artificial intelligence (AI) agents. Drilling of the wellbore is simulated a plurality of times using each of the one or more BHAs, thereby producing a plurality of simulations. Each simulation is generated using a different one of the AI agents. The method also includes generating one or more outputs in response to simulating drilling the wellbore.

A non-transitory computer-readable medium is also disclosed. The medium stores instructions that, when executed by at least one processor of a computing system, cause the computing system to perform operations. The operations include receiving a plurality of inputs. The inputs include one or more properties of a plurality of bottom hole assemblies (BHAs). The one or more properties include a size of a drill bit of the BHAs, a size of a motor of the BHAs, an amount of bend in the BHAs, or a combination thereof. The inputs also include a planned trajectory of a wellbore. The inputs also include one or more properties of a subterranean formation into which the wellbore will be drilled. The operations also include simulating drilling the wellbore in the subterranean formation based at least partially upon the inputs. Drilling of the wellbore is simulated with one or more artificial intelligence (AI) agents. Drilling of the wellbore is simulated a plurality of times using each of the BHAs, thereby producing at least a first simulation and a second simulation for each BHA. The one or more properties of the subterranean formation are different for the first and second simulations. The operations also include generating a plurality of outputs in response to simulating drilling the wellbore. A first of the outputs includes a reward.

A computing system is also disclosed. The computing system includes one or more processors and a memory system. The memory system includes one or more non-transitory computer-readable media storing instructions that, when executed by at least one of the one or more processors, cause the computing system to perform operations. The operations include receiving a plurality of inputs. The inputs include one or more properties of a plurality of bottom hole assemblies (BHAs). The one or more properties include a size of a drill bit of the BHAs, a size of a motor of the BHAs, an amount of bend in the BHAs, or a combination thereof. The inputs also include a planned trajectory of a wellbore. The inputs also include one or more properties of a subterranean formation into which the wellbore will be drilled. The operations also include simulating drilling the wellbore in the subterranean formation based at least partially upon the inputs. Drilling of the wellbore is simulated with one or more artificial intelligence (AI) agents. Drilling of the wellbore is simulated a plurality of times using each of the BHAs, thereby producing at least a first simulation and a second simulation for each BHA. The one or more properties of the BHAs and the planned trajectory of the wellbore remain the same for the first and second simulations. The one or more properties of the subterranean formation are different for the first and second simulations. The operations also include generating a plurality of outputs in response to simulating drilling the wellbore. The plurality of outputs include a direction of a tool face of the BHAs for each of the simulations, a simulated trajectory of the wellbore for each of the simulations, a tortuosity of the simulated trajectory for each of the simulations, a dog-leg severity (DLS) for each of the simulations, a reward for each of the simulations, and a success rate for each of the BHAs. The operations also include selecting one of the BHAs based at least partially upon the one or more outputs. The operations also include causing a drilling rig to drill the wellbore in the subterranean formation using the selected BHA.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a conceptual view of a system for calculating risk of failure in a wellbore environment, e.g., during or prior to drilling, according to an embodiment.

FIG. 3 illustrates a flowchart of a method for calculating risk of failure in a wellbore environment, according to an embodiment.

FIG. 4 illustrates an example of an architecture for the system implementing the method, according to an embodiment.

FIG. 5 illustrates an example of interaction between the system and a user, according to an embodiment.

FIG. 6 illustrates a flowchart of a method for drilling, according to an embodiment.

FIG. 7 illustrates a cross-sectional side view of a BHA, according to an embodiment.

FIG. 8 illustrates a flowchart of a method for evaluating one or more BHAs in a simulated environment, according to an embodiment.

FIG. 9 illustrates a plurality of outputs generated in response to a simulation of a first BHA drilling the wellbore, according to an embodiment.

FIG. 10 illustrates a plurality of outputs generated in response to a simulation of a second BHA drilling the wellbore at a first depth (e.g., 1350 feet), according to an embodiment.

FIG. 11 illustrates a plurality of outputs generated in response to the simulation of the second BHA drilling the wellbore at a second depth (e.g., 1590 feet), according to an embodiment.

FIG. 12 illustrates a plurality of outputs generated in response to a simulation of a third BHA drilling the wellbore, according to an embodiment.

FIG. 13 illustrates a plurality of outputs generated in response to a simulation of a fourth BHA drilling the wellbore, according to an embodiment.

FIG. 14 illustrates the outputs of the (e.g., four) BHAs compared against one another, according to an embodiment.

FIG. 15 illustrates an example of a computing system for performing one or more of the methods disclosed herein, in accordance with some embodiments.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

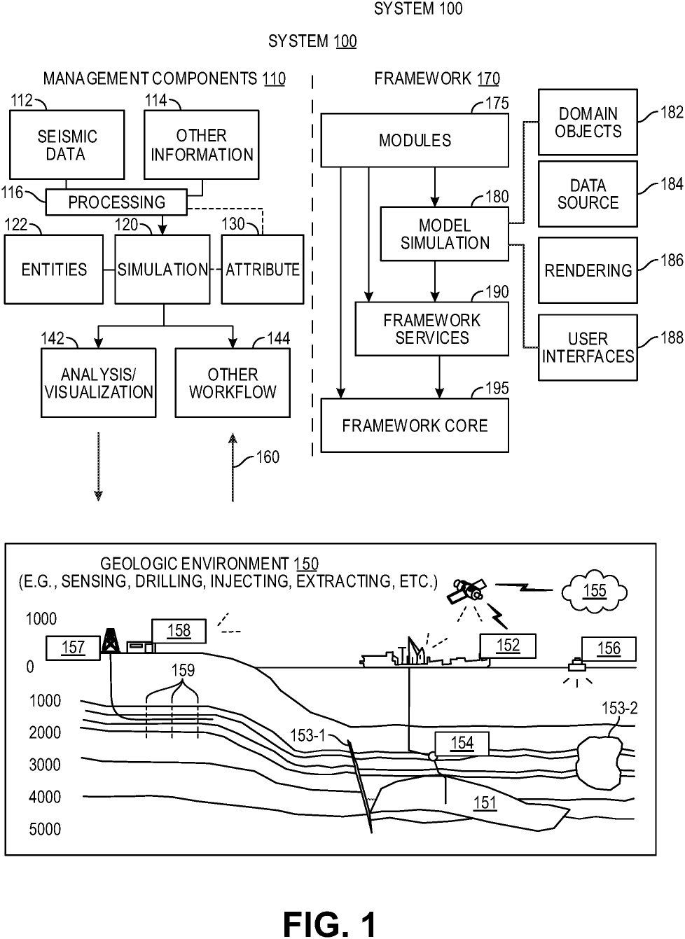

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT® .NET® framework (Redmond, Washington), which provides a set of extensible object classes. In the .NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (Schlumberger Limited, Houston Texas), the INTERSECT™ reservoir simulator (Schlumberger Limited, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

In an example embodiment, the management components 110 may include features of a commercially available framework such as the PETREL® seismic to simulation software framework (Schlumberger Limited, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (Schlumberger Limited, Houston, Texas) allows for integration of add-ons (or plug-ins) into a PETREL® framework workflow. The OCEAN® framework environment leverages .NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN®framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results, and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures), or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

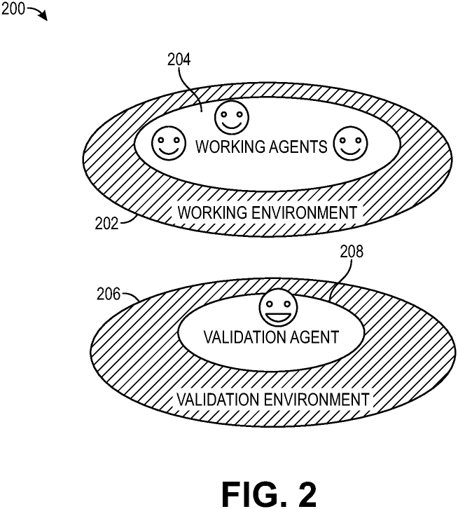

FIG. 2 illustrates a conceptual view of a system 200 for calculating risk of failure in a wellbore environment, e.g., during or prior to drilling, according to an embodiment. The system 200 may include a working environment 202 that includes a pool of working agents 204, e.g., homogenous agents and heterogeneous agents. In this context, an “environment” is an algorithmic component in a reinforcement learning framework. It includes a simulator (or real plant, e.g., an actual field system) where an action may be applied, and a reward system for evaluating the response to this action. The working environment 202 may also include a representation of the current drilling operations, e.g., rig state, geology, bit location (e.g., with respect to the planned trajectory), etc. The system 200 may also include a validation environment 206 having one or more validation agents 208. It will be appreciated that “agents” refers to computer-implemented software and/or hardware or parts thereof.

In some embodiments, the system 200 may calculate risk of failure for an action. The action may be proposed by the working agents 204 in the working environment 202, and the risk may be calculated in the validation environment 206. In some embodiments, the risk may be calculated using a DQN to evaluate the following relationship:

$${Q}^{x} \left({s}_{t} , {α}_{t}\right) = \underline{E} \left({R}_{t + 1} + γ {R}_{t + 2} + {γ}^{2} {R}_{t + 3} + … \left|{δ}_{t} , {α}_{t}\right)\right)$$

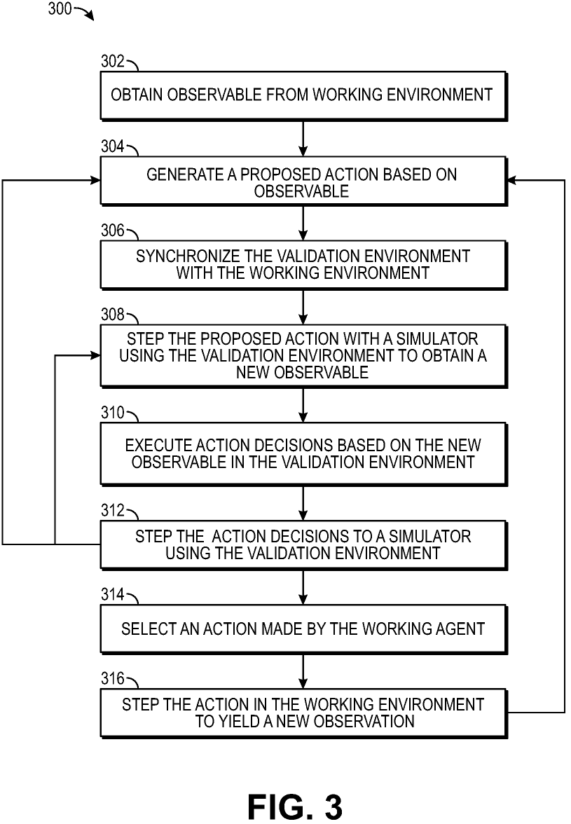

FIG. 3 illustrates a flowchart of a method 300 for calculating risk of failure while drilling a well, according to an embodiment. The method 300 may include receiving an observable from the working environment, as at 302. An observable may be a state observed from an environment, such as a survey point during drilling. The observable event may be the survey carried out in the field. In other embodiments, observables may be anything that may call for a drilling action in response.

As noted above, the working environment 202 may include multiple working agents 204. Each working agent 204 may be employed by the method 300 to generate a proposed action based on (e.g., in response to) the observable, as at 304. Proposed actions may include adjustments to toolface settings, sliding ratios, and/or other drilling parameters. The method 300 may then include synchronizing the validation environment 208 with the working environment 202, so that the validation environment 208 accurately represents the current state of the drilling environment 202, e.g., the position, operating parameters, and/or state of drilling equipment, the formation properties, etc.

The method 300 may then include stepping the proposed action with a simulator, in the validation environment 208, so as to yield a new observable, as at 308. Thus, after stepping the simulation, the validation environment 208 represents the drilling environment in a hypothetical case in which the proposed action has been implemented. The validation agent 206 may then execute action decisions on the new observable in the validation environment 206, as at 310. The validation environment 206 may then step the action decided upon by the validation agent 206 in the simulator, as at 312. The worksteps of proposing action, making decisions, and stepping in the simulator may then be repeated, e.g., until the validation agent 208 finishes a drilling analysis, e.g., until the validation environment, executing the different steps, reaches a target location. From this analysis, the method 300 may include calculating a reward using the validation agent 208. The preceding aspects may then be repeated for the remaining working agents and the actions proposed by these other working agents, if any, as indicated in FIG. 3.

The method 300 may then select an action proposed by one of the working agents 204 based on the reward, as at 314. For example, the method 300 may include selecting a proposed action that yields the maximum reward (R) according to the drilling analysis performed by the validation agent. The action that is selected may then be returned to the working environment 204, as at 316. For example, a drilling rig may be adjusted to implement the action. The process of acquiring working agent decision steps for a remainder of the drilling may then repeat, based on the new observation obtained. This may repeat, e.g., throughout the drilling process.

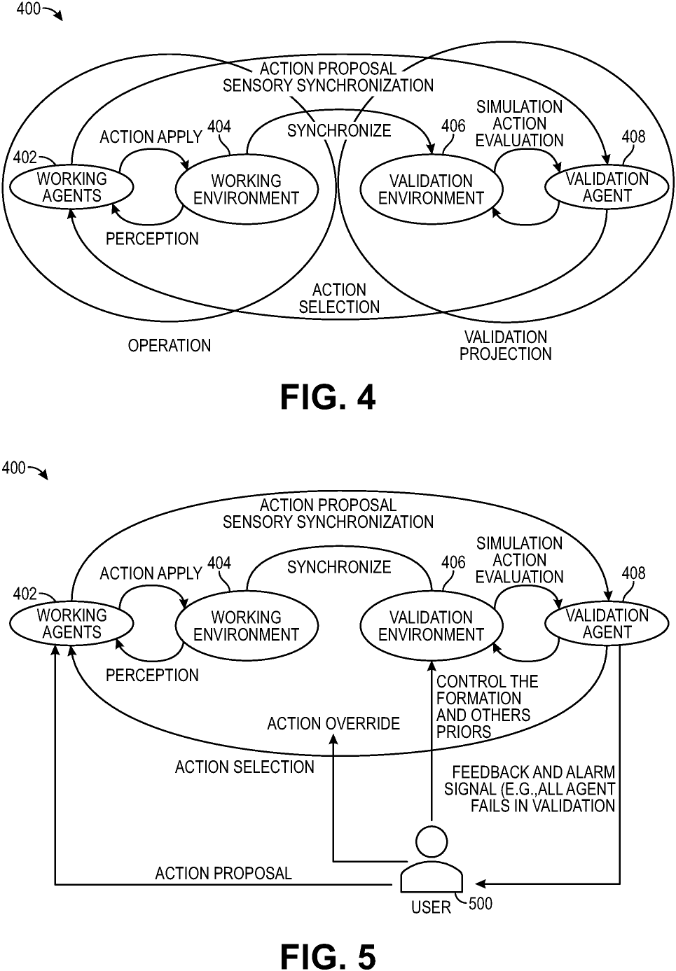

FIG. 4 illustrates an example of an architecture for a system 400 implementing the method 300, according to an embodiment. As shown, the working agents 402 and working environment 404 may be part of an “operation” side of the architecture, while a validation projection side of the architecture may include the validation environment 406 and the validation agent 408.

The working agents 402, working environment 404, validation environment 406, and validation agent 408 interact. In particular, the working agents 402 may apply actions to the working environment 404, and receive perceptions (e.g., sensor measurements) therefrom, e.g., a state of the working environment 404. The working environment 404 may synchronize with the validation environment 406. The validation environment 406 may evaluate actions by way of simulation through the validation agent 408, which may provide results of the simulation back to the validation environment 406. Further, the working agents 404 may provide action proposal sensory synchronization to the validation agent 408, which may provide action selections back to the working agents 404. The action may then be fed to the working environment 406, which may, for example, cause a drilling rig to implement the selected drilling action.

Embodiments of the method 300 can implement the validation agent 408 to run multiple times, potentially in different configurations, for a single action proposed by one or more working agents 404. For example, the validation agent 408 can be configured to prioritize efficiency in the drilling process, or minimization of risk, to name just two examples of different possible configurations for the validation agent 408. Further, in at least some examples, two or more different (and differently configured) validation agents 408 may be provided and may be used to perform the drilling analysis separately, e.g., in parallel, to generate a reward associated with an action proposed by one or more of the working agents 402. In some embodiments, the highest total reward may be used, but in others, the average total reward or lowest total reward may be used. The reward calculated, e.g., in one of these ways, may then be compared with the rewards, calculated the same or similarly, for other proposed actions, thereby permitting the machine-generated proposed actions to be quantitatively compared and automatically selected.

Further, by providing interaction between working agents 402 and validation agents 408, passing proposals and selections back and forth, more stable decision making may result, because agreement between working agent 402 and validation agent 408 may prevent irrational choices by either. Additionally, the validation agent 408 may present an empirical evaluation through simulation.

FIG. 5 illustrates an example of the interaction between the system 400 and a human user 500, according to an embodiment. As shown, the user 500 may have input into the working agents 402, the action selection, and the validation environment 406. For example, the user 500 may provide an action proposal, which may be added to the actions proposed by the working agents 402, and may compete therewith in the drilling analysis conducted by the validation agent 408. The user may also override the action selected by the validation agent 408. The user may also control the formation and/or any other characteristic of the validation environment, e.g., based on offset well data and/or experience. The validation agent 408 may also provide feedback and alarm signals (e.g., failure of the drilling actions proposed by the working agents 402 to produce a viable well) to the user 500, so the user 500 may take mitigating actions. As such, the system 400 may provide environmental detection, etc., and may be able to perform most tasks autonomously, but human feedback/override may still be available.

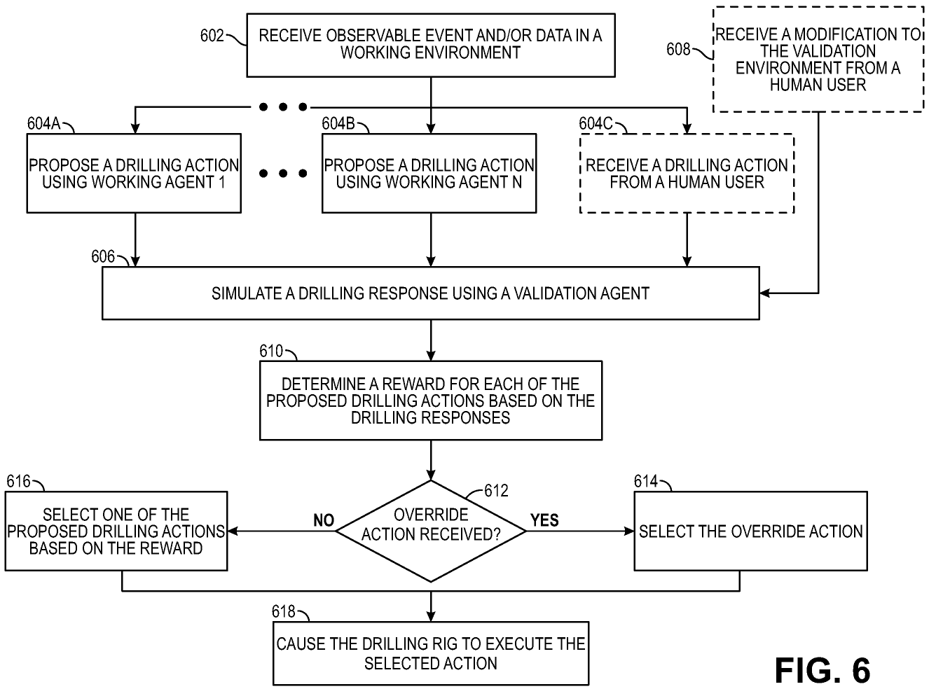

FIG. 6 illustrates another method 600 for drilling, according to an embodiment. As with the method 400 of FIG. 4, the present embodiment may implement a bifurcated architecture in which working agents may make proposals for drilling actions and one or more validation agents may evaluate these proposals in a validation environment. Moreover, the method 600 may be subject to human intervention and/or override, as will be described.

As shown, the method 600 may include receiving an observable event and/or data in a working environment, as at 602. For example, the observable may include one or more sensor measurements representing, for example, a position of a drill bit in the earth, and a comparison thereof to a planned trajectory.

The method 600 may then include proposing a drilling action using potentially several (e.g., 1, 2, ..., N) working agents, as at 604A, 604B. Each working agent may be configured to interpret data differently, e.g., may be tuned for different types of environments, may implement rules-based algorithms, different machine-learning models (e.g., of different types or trained using different data specific to different situations).

In some embodiments, the method 600 may also include receiving a drilling action proposed by a human user, as at 604C. This drilling action, which may be based on intuition, field experience, etc. may be used as a competitive drilling action proposal, and may be evaluated alongside the machine-generated proposals.

One or more validation agents may then simulate drilling responses for the actions proposed by the working agents, as at 606. In some embodiments, one validation agent may evaluate the drilling proposals from each of the working agents. In other embodiments, different validation agents may evaluate drilling actions from different working agents. For example, a different validation agent may be used for each different working agent, or there may be overlap between the drilling proposals evaluated by the different validation agents. Thus, any combination of working agents and validation agents may be provided. In a specific embodiment, several validation agents may be used, e.g., tuned to prioritize different goals, e.g., one may be tuned for efficiency, another for speed, another for risk, another for maintaining strict adherence to a planned trajectory, etc.

In some embodiments, the validation environment, e.g., drilling parameters, geological characteristics of the subsurface domain, etc., may be modified by a user before or during the simulating at 606. For example, the method 600 may include receiving a modification to the validation environment from a human user, as at 608. The validation agents may then use the modified validation environment in order to evaluate the proposed drilling actions, which may or may not include a human-proposed drilling action.

Using the validation agent(s), the method 600 may include determining a reward for each of the proposed drilling actions based on the drilling responses calculated using the validation environment, as at 610. For example, the validation agents may simulate a drilling scenario for each of the proposed actions, determining the risk of each resulting in failure, the efficiency in the drilling process, etc. The calculation of the drilling scenario may be accomplished solely by the validation agents running through the simulation of the entire scenario, or could be accomplished by recursively pushing incremental drilling responses back to the working environment, for the working agents to then propose next actions, until the end of the drilling scenario is reached. In an embodiment, the working agents propose a set of actions, and each action is individually evaluated by the validation agent in the validation environments. When the validation agent evaluate, a projected total future reward score, or estimated total reward (ETR), is calculated for each action. The final action is the one with the maximum ETR.

In some embodiments, the reward may be a quantification of a risk of failure for a given action, e.g., the DQN equation provided above. In other embodiments, other quantifications of a reward for a proposed action may be employed. The rewards may be different as calculated between different validation agents, and thus may be combined, e.g., using an average, taking a minimum/maximum, or using any other statistical method.

The method 600 may again account for human intervention, e.g., in the form of an override. Accordingly, at 612, the method 600 may provide an opportunity for a manual override of the proposed actions, e.g., in which a human operate selects an action notwithstanding, or at least not strictly adhering to, the rewards calculation by the validation agents. If an override is received (612: Yes), the override is selected, as at 614. Otherwise (612: No), the method 600 may include selecting one of the proposed drilling actions (either a computer-generated or user-entered action) based on the calculated reward, as at 616. The method 600 may then feed the selected drilling action back to the working agent, which may cause the working environment to be manipulated, e.g., by causing the drilling rig to execute the selected action, as at 618.

System and Method for Testing and Evaluating BHAs in a Simulated Environment Using Directional Drilling Artificial Intelligence (AI) Agents

The present disclosure evaluates a plurality of BHAs using one or more AI agents (e.g., working agents 204 and/or validation agents 208) in a simulated environment. For each BHA configuration, a sequence of drilling actions may be performed by the AI agents in the simulated environment. Each simulation may yield one or more outputs. One of the BHAs may then be selected based at least partially upon the outputs.

Thus, the present disclosure may test and evaluate the BHAs using the AI agents (also referred to as DD-net). In one embodiment, rather than testing a single BHA at a single depth in the simulated environment, the systems and methods described herein may test a plurality of BHAs using a plurality of configurations with a plurality of drilling activity sequences guided by the AI agents. In other words, the multi-agent DD-net may drill a predetermined trajectory with a plurality of candidate BHAs, and outputs of the simulations may be evaluated to select one of the candidate BHAs.

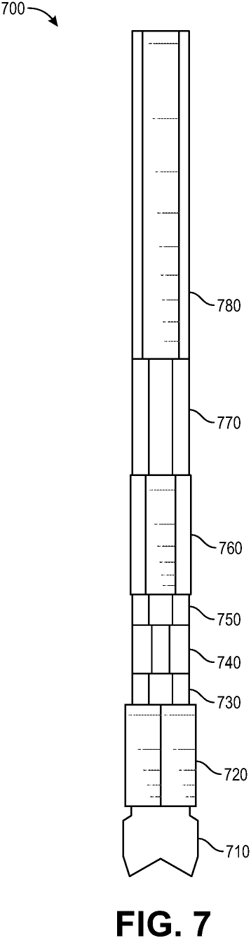

FIG. 7 illustrates a cross-sectional side view of a BHA 700, according to an embodiment. As shown, the BHA 700 may include a drill bit 710, a motor 720, a first (e.g., lower) crossover sub 730, a first (e.g., lower) drill collar 740, a second (e.g., upper) crossover sub 750, a measurement-while-drilling (MWD) tool and/or a logging-while-drilling (LWD) tool 760, a second (e.g., upper) collar 770, and a tool joint 780. As will be appreciated, the BHA 700 is merely one example of a BHA, and other BHAs may include other components and/or other configurations.

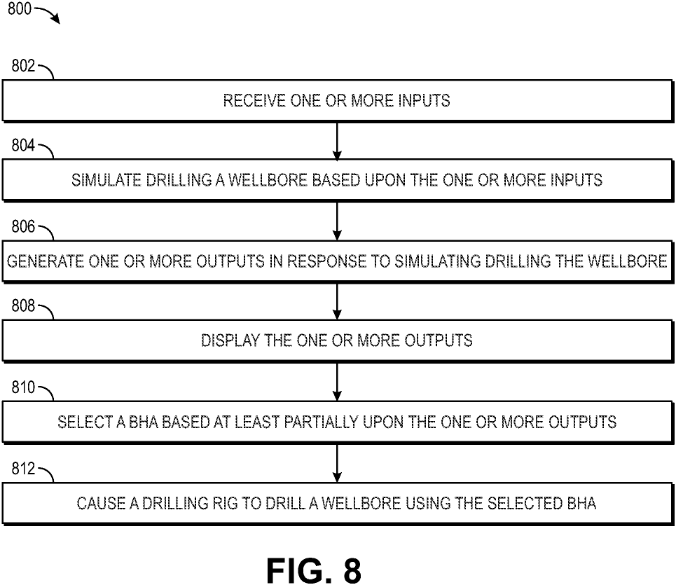

FIG. 8 illustrates a flowchart of a method 800 for evaluating one or more BHAs in a simulated environment, according to an embodiment. An illustrative order of the method 800 is provided below; however, one or more steps of the method 800 may be performed in a different order, combined, split into sub-steps, repeated, or omitted without departing from the scope of this disclosure.

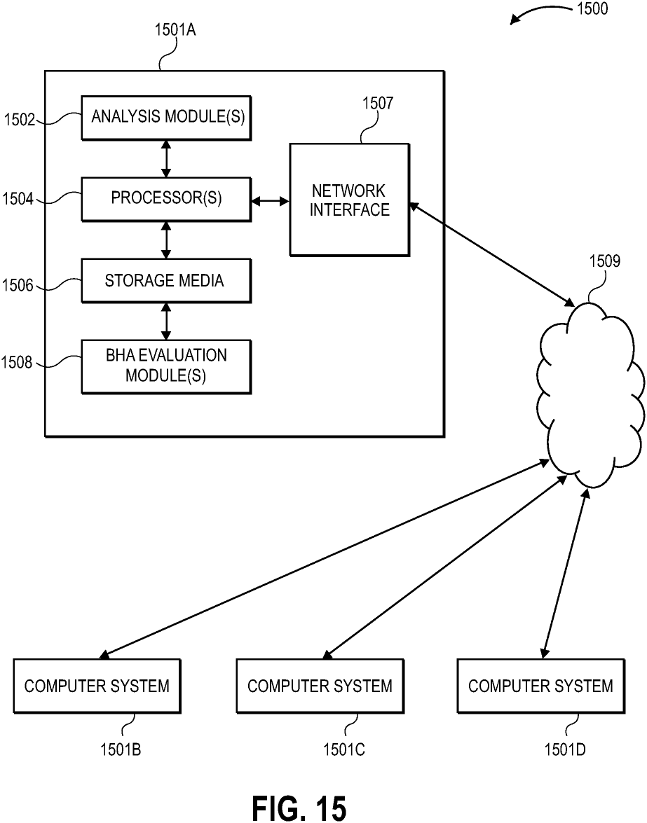

The method 800 may include receiving one or more inputs, as at 802. The inputs may be received by a computing system (e.g., the computing system described below with reference to FIG. 15). The inputs may include properties of the BHA(s) to be evaluated. The properties may be or include the components in the BHA 700, the order of the components in the BHA 700, a type of the drill bit 710, a size of the drill bit 710, a shape of the drill bit 710, an angle of bend in the BHA 700 (e.g., for directional drilling), or a combination thereof. For example, there may be four BHAs to be evaluated. The first BHA may have an 8.75ʺ drill bit, an 8.5ʺ stabilizer on the motor, and a 2.12° bend. The second BHA may have an 8.75ʺ drill bit, an 8.625ʺ stabilizer on the motor, and a 1.5° bend. The third BHA may have an 8.75ʺ drill bit, an 8.5ʺ stabilizer on the motor, and a 1.83° bend. The fourth BHA may have an 8.75ʺ drill bit, a slick motor sleeve, a string stab 8.5ʺ above the motor, and a 2.12° bend.

The inputs may also or instead include the planned trajectory of the wellbore to be drilled (e.g., the width, the depth, the turns, etc.). The inputs may also or instead include the formation configuration. The formation configuration may be or include the properties of the subterranean formation into which the wellbore will be drilled (e.g., the depths of the layers, the materials of the layers, etc.). The inputs may also or instead include drilling decisions from offset wellbores.

The method 800 may also include simulating drilling a wellbore based upon the one or more inputs, as at 804. In other words, the wellbore may be drilled in a simulated environment based upon the one or more inputs. The drilling of the wellbore may be simulated by the computing system. The wellbore may be drilled one or more times in the simulated environment using each of the BHAs to be evaluated. For example, the first BHA may drill the wellbore a plurality of times in the simulated environment, the second BHA may drill the wellbore a plurality of times in the simulated environment, and so on.

The BHAs may have the properties provided in the inputs. The properties for each BHA may remain constant for each simulation. The wellbore may have the planned trajectory provided in the inputs. The planned trajectory may remain constant for each simulation. The subterranean formation into which the wellbore is drilled may have the properties provided at the inputs. The properties of the subterranean formation may vary from one simulation to the next. This may be what causes the outputs to vary from one simulation to the next.

The wellbore may be drilled (e.g., the simulation may be performed) using one or more of the AI agents. The AI agents may be selected or modified (e.g., optimized) based at least partially upon an amount of deviation from the planned drilling trajectory, the cost (e.g., time) of the drilling operation, rate of penetration (ROP), or a combination thereof.

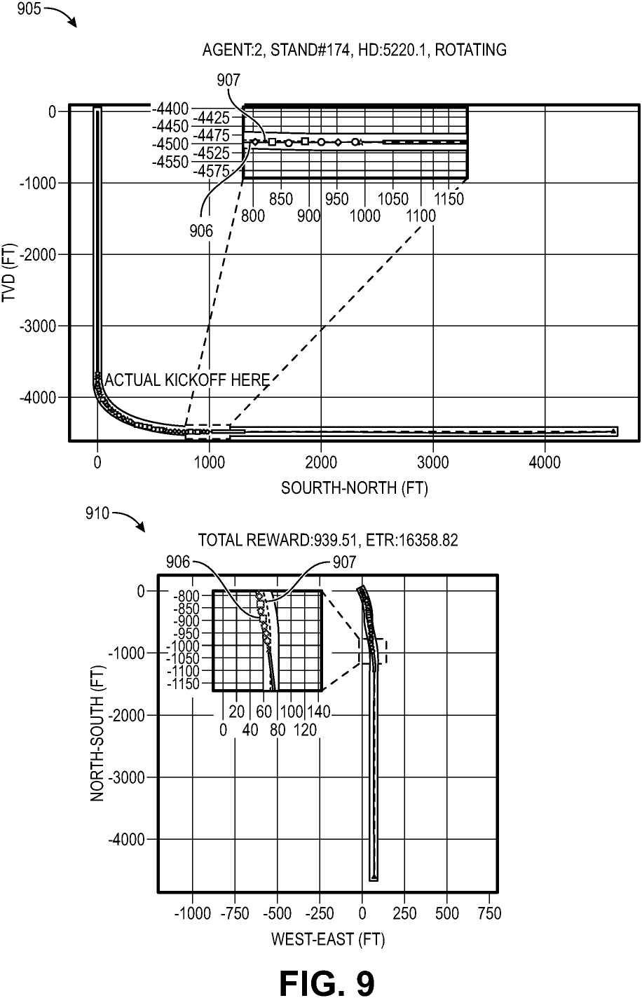

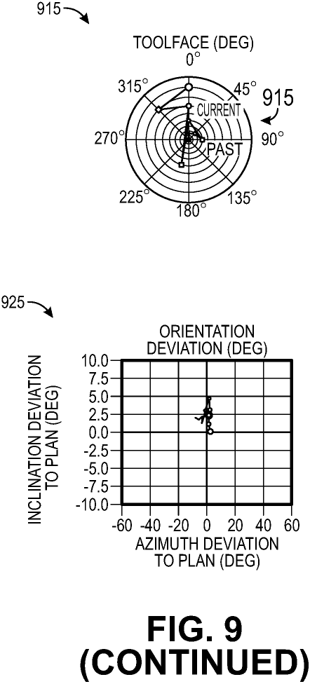

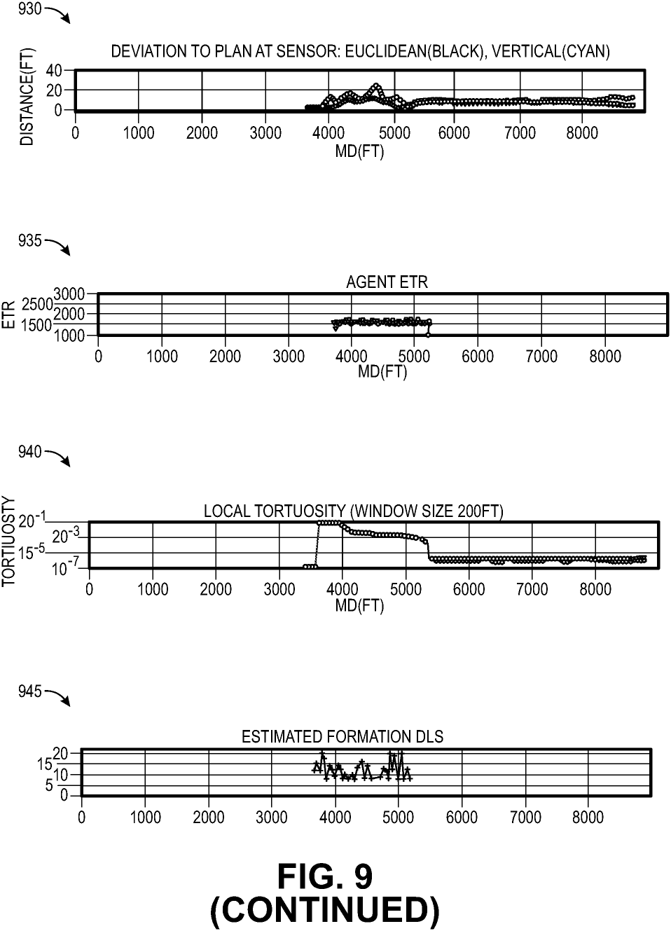

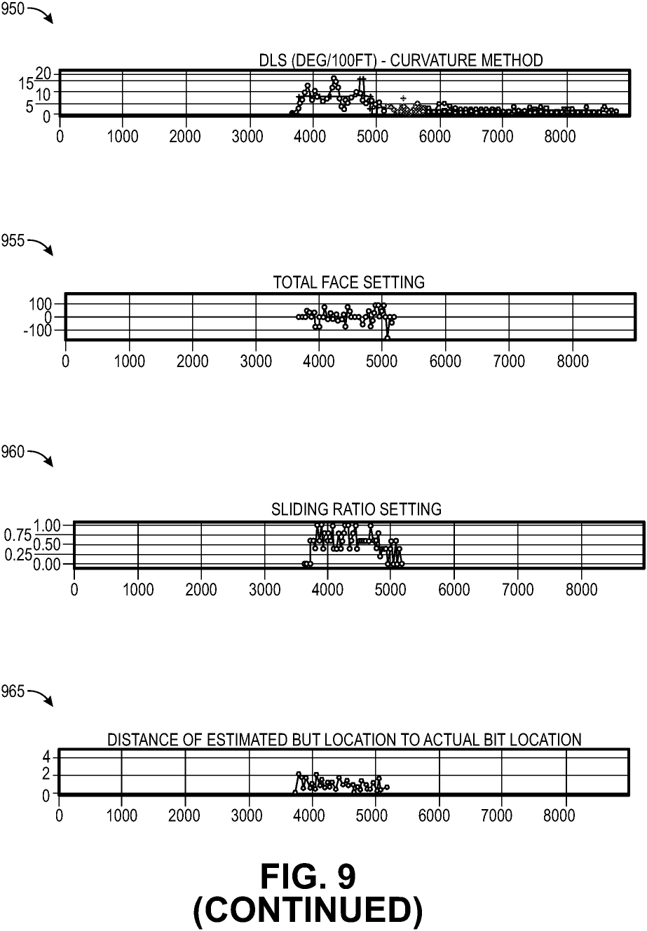

The method 800 may also include generating one or more outputs in response to simulating drilling the wellbore, as at 806. The outputs may be generated by the computing system. FIG. 9 illustrates a plurality of outputs generated in response to a simulation of the first BHA drilling the wellbore, according to an embodiment. The outputs may include a comparison of the simulated drilling trajectory to the planned drilling trajectory. The graph 905 illustrates a side view of the wellbore, and the graph 910 illustrates a plan view of the wellbore. The enlarged portions of the graphs 905, 910 show the simulated drilling trajectory of the wellbore (solid line) 906 and the planned drilling trajectory of the wellbore (dashed line) 907.

The outputs may also or instead include a direction of the tool face of the BHA (e.g., in degrees) while simulating drilling along the planned drilling trajectory, which is shown in the graph 915.

The outputs may also or instead include a deviation of the simulated drilling trajectory from the planned drilling trajectory, which is shown in the graph 925. For example, the graph 925 shows the deviation of the azimuth of the simulated drilling trajectory from the azimuth of the planned drilling trajectory on the X axis (e.g., in degrees), and the deviation of the inclination of the simulated drilling trajectory from the inclination of the planned drilling trajectory on the Y axis (e.g., in degrees). The deviation may be a maximum deviation and/or an average deviation.

The outputs may also or instead include a deviation of the simulated drilling trajectory from the planned drilling trajectory (e.g., in distance), which is shown in the graph 930. The deviation may be a maximum deviation and/or an average deviation.

The outputs may also or instead include an estimated total reward (ETR) for the AI agent performing the simulation, as shown in the graph 935. The ETR may be determined after the current simulation begins and before the current simulation ends (e.g., while drilling is partially complete). The ETR refers to a sum of a current reward for the current simulation and an estimated future reward for the current simulation. The current reward covers the beginning of the simulation to the current point in the simulation, and the future reward covers the current point in the simulation to the end of the simulation. The current reward, the future reward, or both may be based at least partially upon one or more of the other outputs (e.g., the direction of the tool face, the single action risk matrix, the deviation of the trajectory, the tortuosity, the DLS, the tool face setting, the sliding ratio setting, or a combination thereof). For example, the current reward, the future reward, or both may be based upon (1) a deviation of the other outputs from the plan during the current simulation (which may be a negative value), (2) an operational efficiency of the BHA during the current simulation (which may be a negative value), (3) drilling rewards during the current simulation (which may be a positive value), (4) how close the simulated drilling gets to the target in the current simulation (which may be a positive value), or a combination thereof.

The outputs may also or instead include a tortuosity of the simulated drilling trajectory, as shown in the graph 940. Tortuosity refers to a measure of deviation from a straight line. More particularly, it is the ratio of the actual distance traveled between two points, including any curves encountered, divided by the straight line distance.

The outputs may also or instead include an estimated dog-leg severity (DLS), as shown in the graph 945. The estimated DLS refers to the DLS capacity of the BHA in the current formation. For example, the formation DLS refers to an estimated amount of the DLS of the BHA in the current formation.

The outputs may also or instead include a measured DLS, as shown in the graph 950. The measured DLS refers to the measured DLS of the BHA in the current formation. The measured DLS may include changes in the hole curvature. The severity of a dog-leg may be determined by the averaging changes in angle and/or direction calculated on the distance over which this change occurs. For example, if there is a 3° change in angle (no direction change) over 100 feet of hole, the dog-leg severity is 3° per 100 feet. The DLS may include a maximum DLS and/or an average DLS. For example, the first BHA may have an average DLS of 23°/100 feet, the second BHA may have an average DLS of 17°/100 feet, the third BHA may have an average DLS of 20°/100 feet, and the fourth BHA may have an average DLS of 15°/100 feet.

The outputs may also or instead include a tool face setting of the BHA, as shown in the graph 955. The tool face setting refers to a direction that the BHA is facing while being steered.

The outputs may also or instead include a sliding ratio setting, as shown in the graph 960. The sliding ratio setting refers to a ratio and/or percentage of distance that the BHA is sliding while drilling the wellbore. The remaining ratio and/or percentage is the distance that the BHA is rotating while drilling the wellbore. The sliding ratio may be determined at different depths.

The outputs may also or instead include a distance between the estimated location of the drill bit and the actual location of the drill bit, as shown in the graph 965.

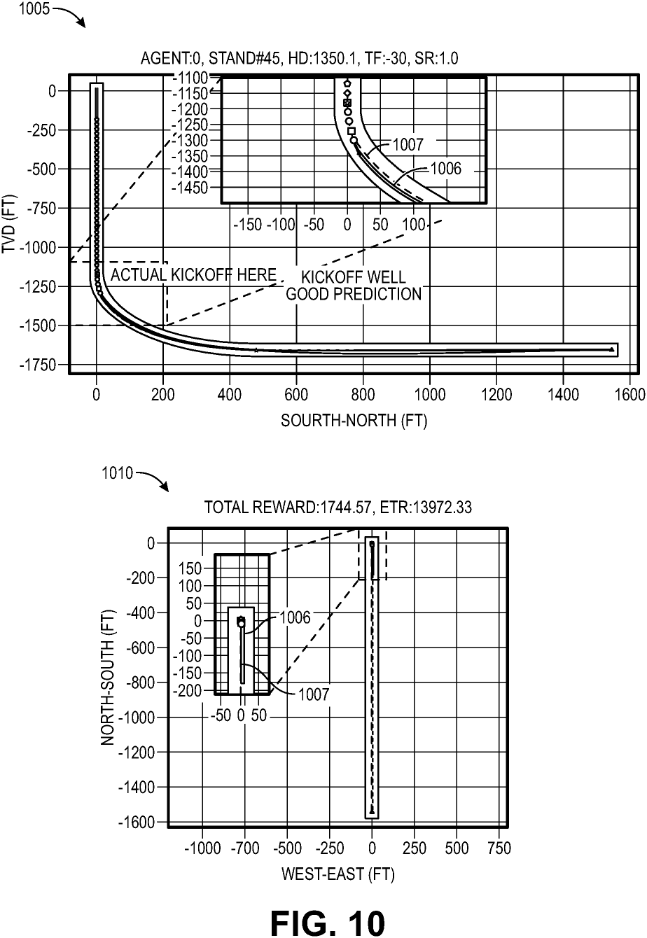

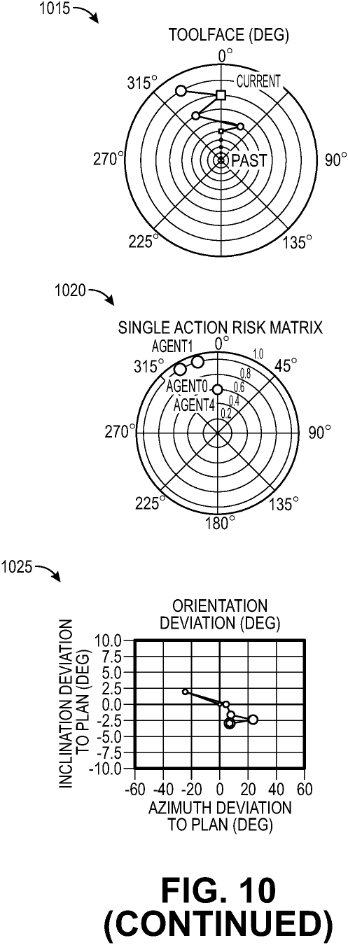

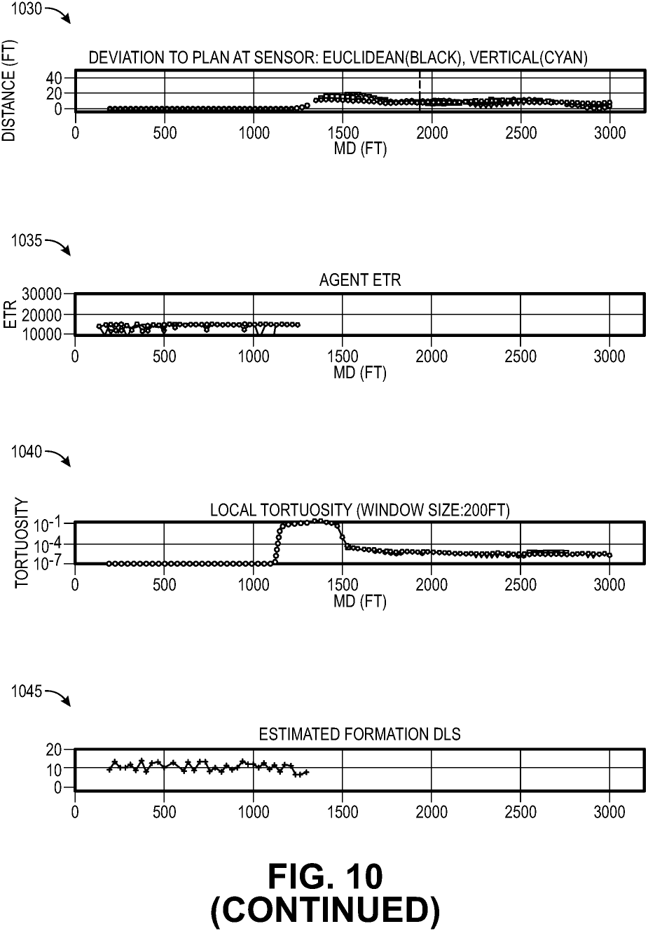

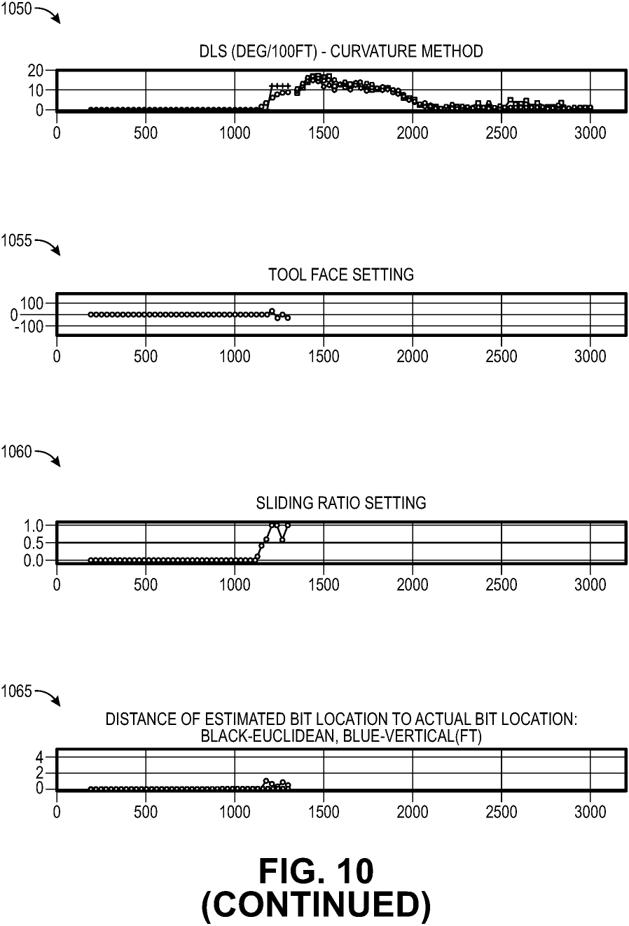

FIG. 10 illustrates a plurality of outputs generated in response to a simulation of the second BHA drilling the wellbore, according to an embodiment. FIG. 10 is generated when the second BHA is at a first depth of about 1350 feet. The outputs in the graphs 1005-1065 correspond to the outputs in the graphs 905-965.

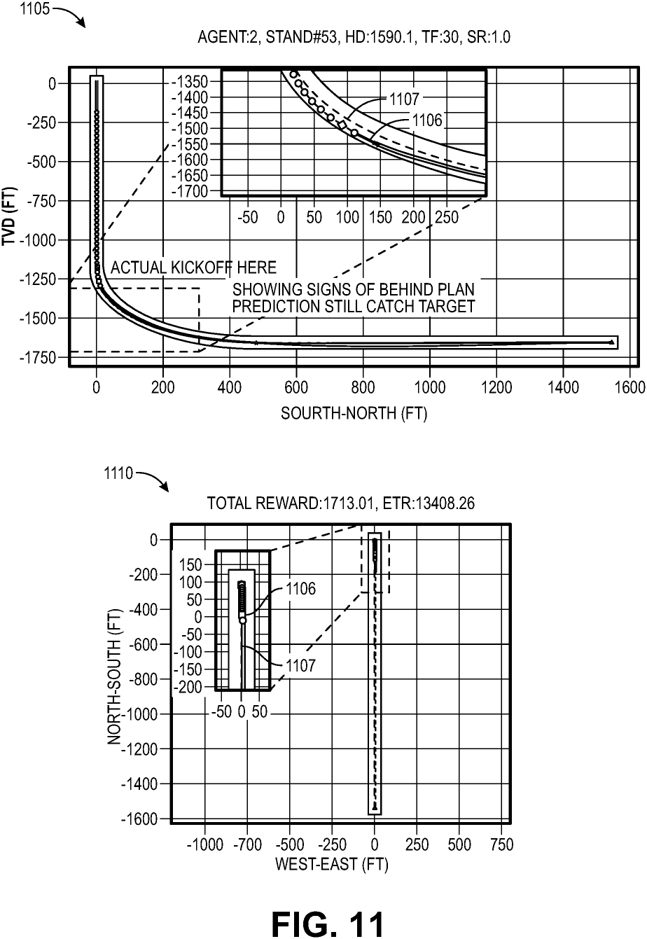

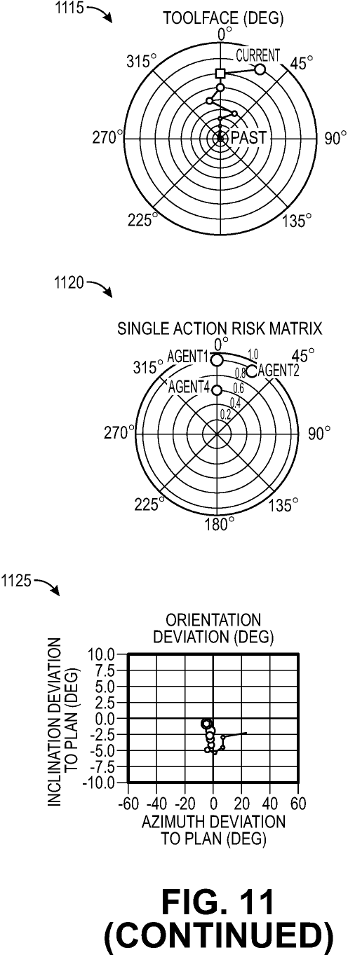

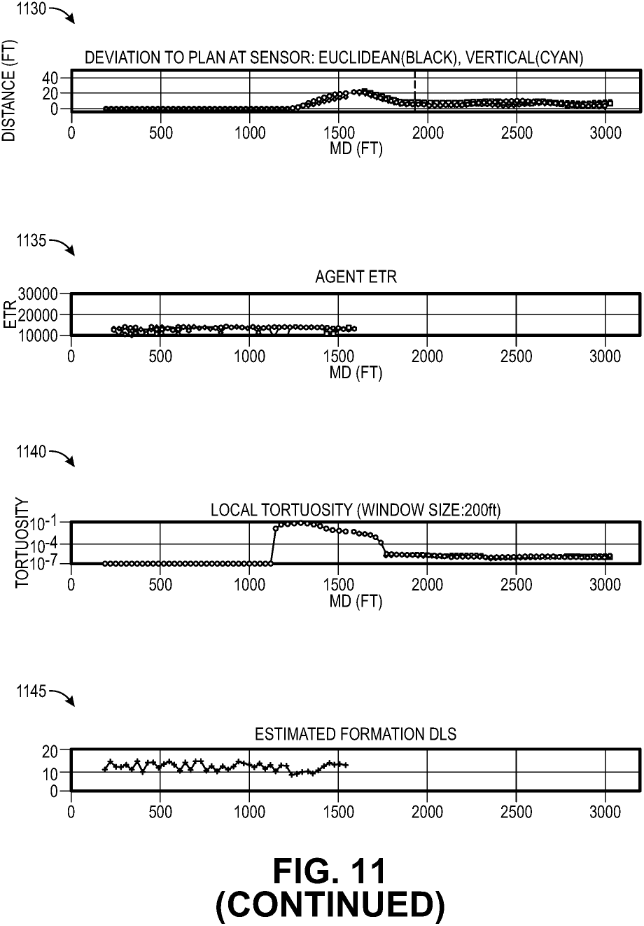

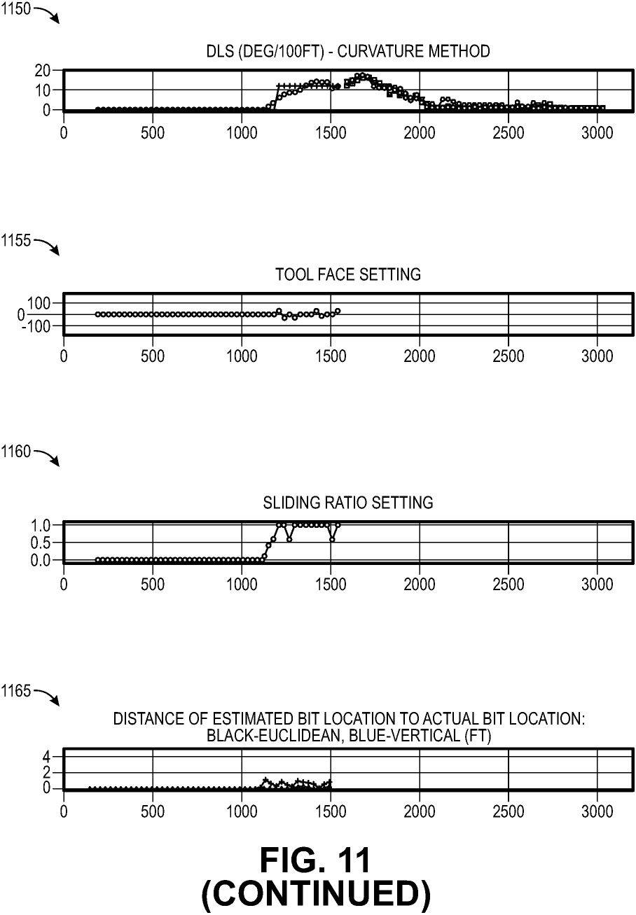

FIG. 11 illustrates a plurality of outputs generated in response to the simulation of the second BHA drilling the wellbore, according to an embodiment. FIG. 11 is generated when the second BHA is at a second depth of about 1590 feet. The outputs in the graphs 1105-1165 correspond to the outputs in the graphs 905-965 and the graphs 1005-1065.

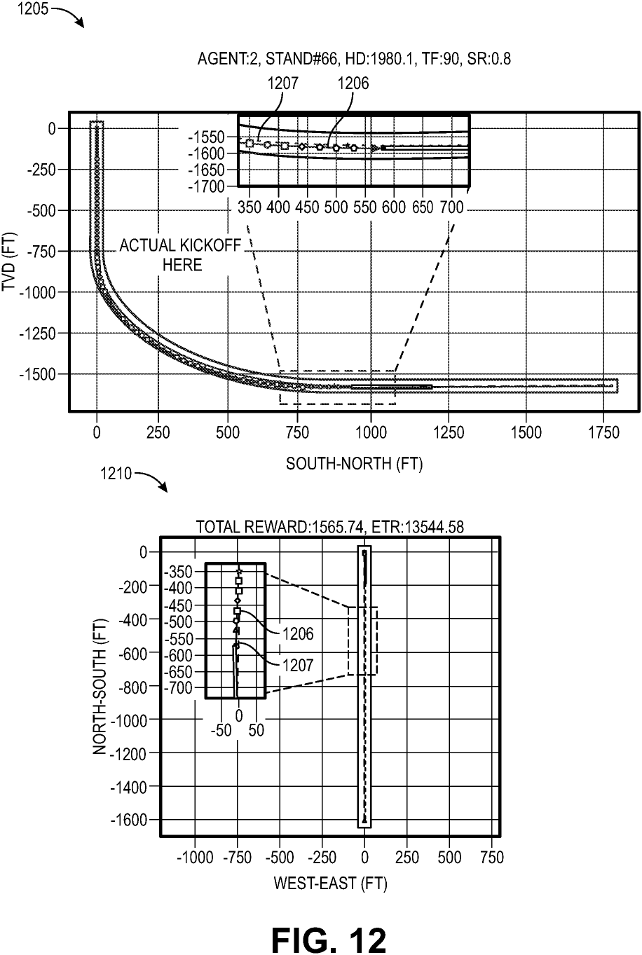

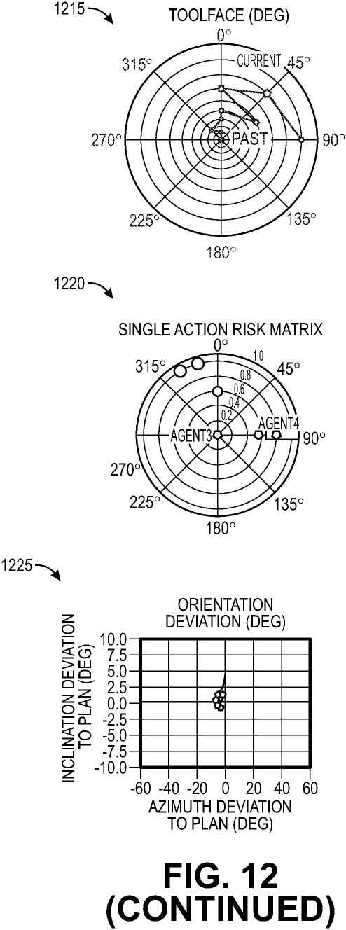

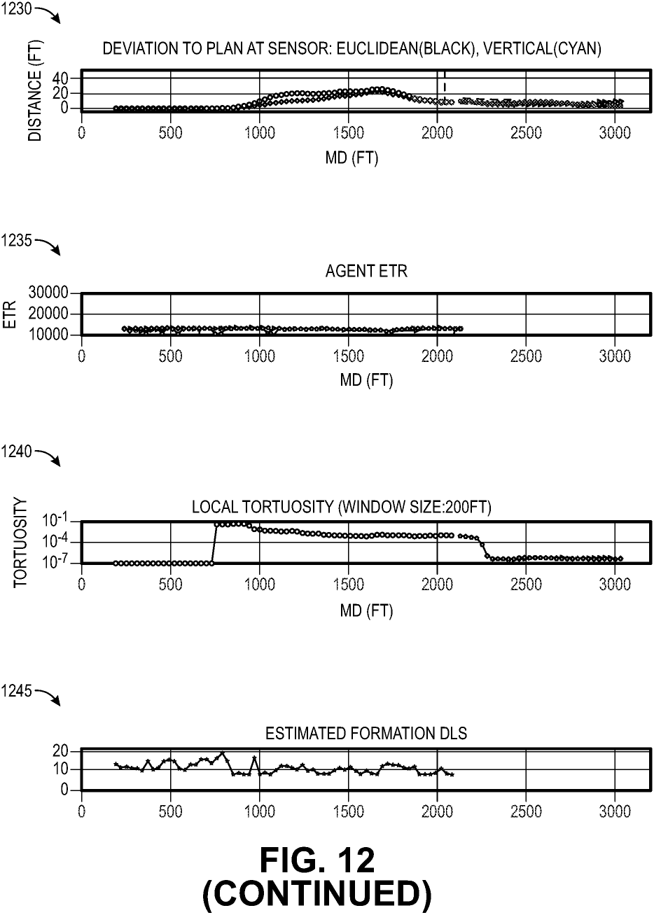

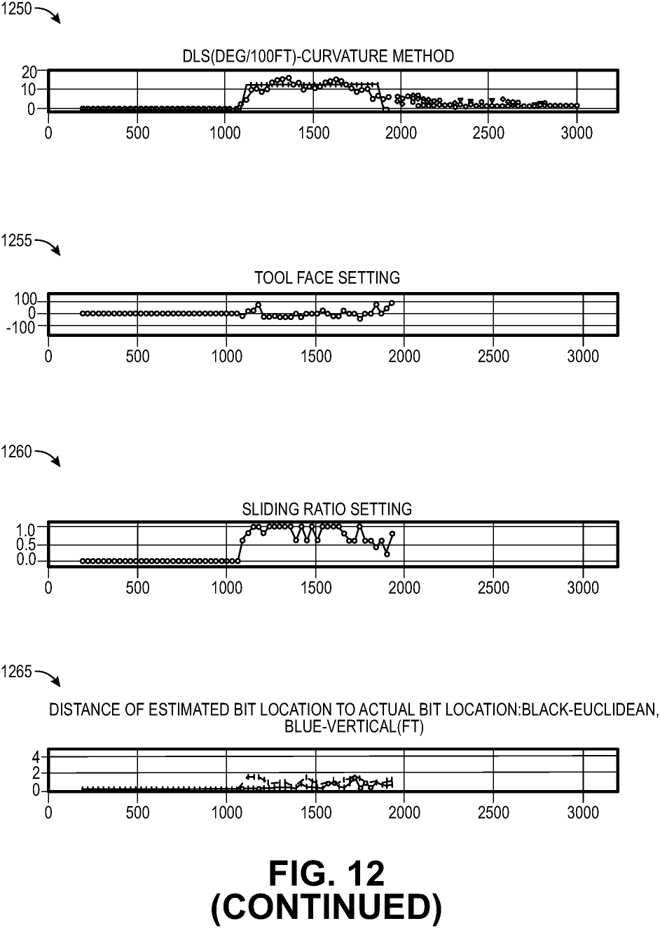

FIG. 12 illustrates a plurality of outputs generated in response to a simulation of the third BHA drilling the wellbore, according to an embodiment. The outputs in the graphs 1205-1265 correspond to the outputs in the graphs 905-965, the graphs 1005-1065, and the graphs 1105-1165.

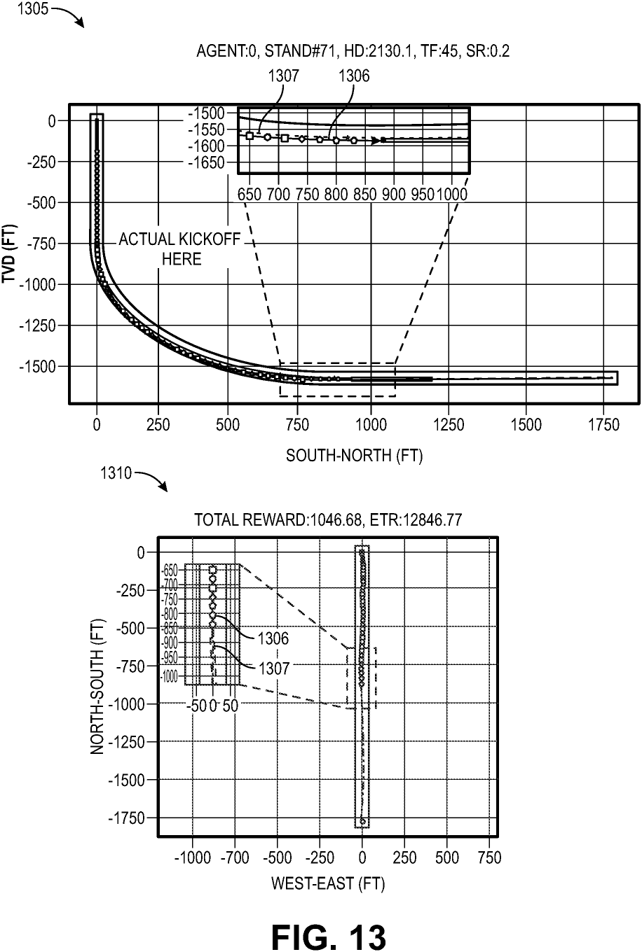

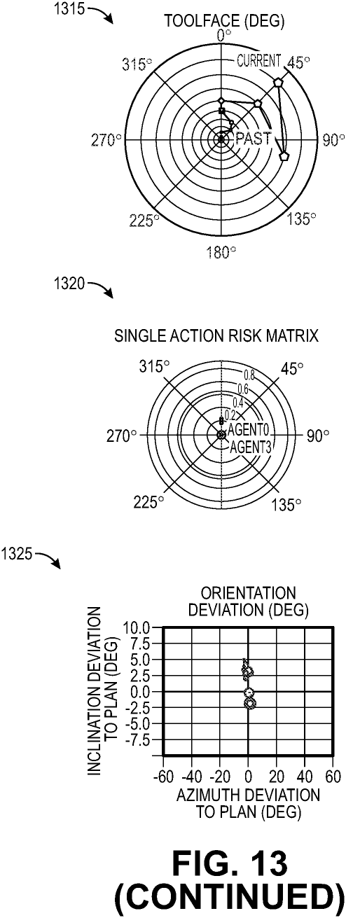

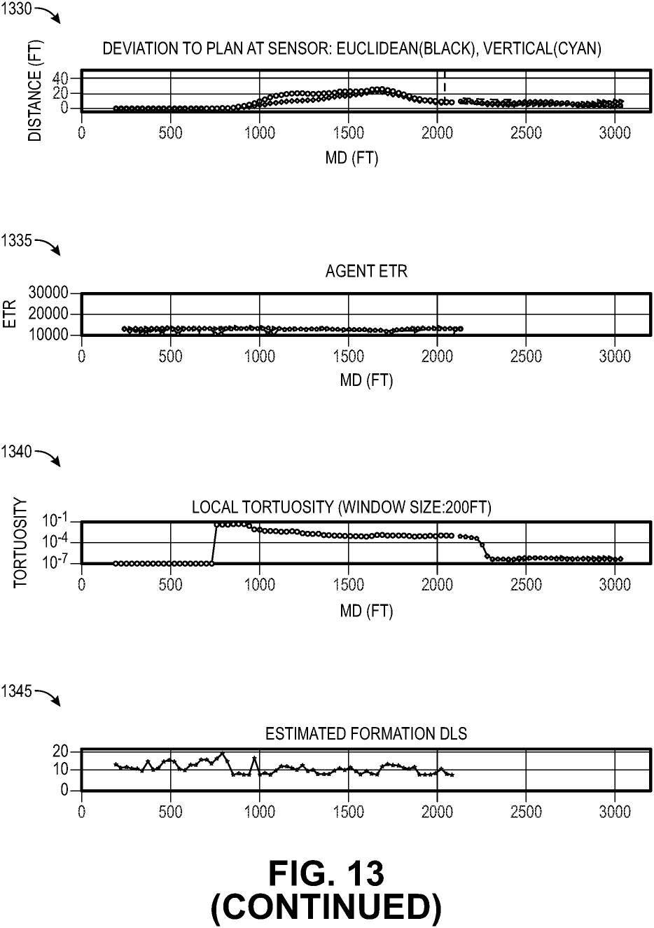

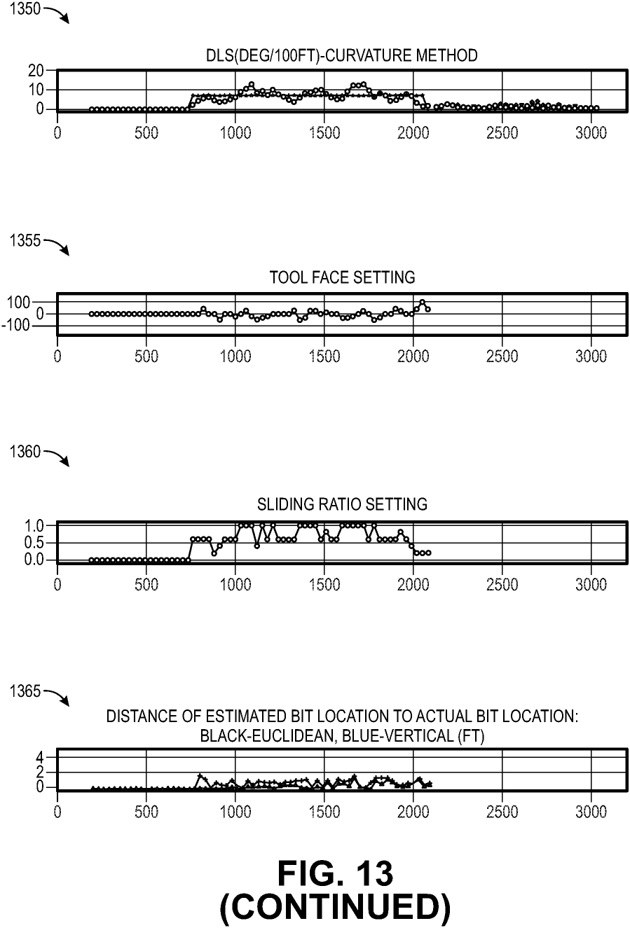

FIG. 13 illustrates a plurality of outputs generated in response to a first simulation of the fourth BHA drilling the wellbore, according to an embodiment. The outputs in the graphs 1305-1365 correspond to the outputs in the graphs 905-965, the graphs 1005-1065, the graphs 1105-1165, and the graphs 1205-1265.

The outputs may also or instead include a success rate (or failure) rate for each of the BHAs being evaluated. Table 1 below illustrates a plurality of simulations for each of the BHAs and the corresponding success rates for each BHA. In the example in Table 1, the first BHA has the highest success rate. In one embodiment, a successful outcome occurs when the BHA drills to within a predetermined distance (e.g., 5 meters) from a target location during a simulation, and an unsuccessful outcome occurs when the BHA does not drill to within the predetermined distance.

TABLE 1

| | Successful Outcomes | Unsuccessful Outcomes | Success Rate |
|---|---|---|---|
| BHA 1 | 84 | 11 | 88.4% |
| BHA 2 | 109 | 20 | 84.5% |
| BHA 3 | 81 | 17 | 82.7% |
| BHA 4 | 24 | 92 | 20.7% |

The outputs may also or instead include the cost in time and/or operation for each of the BHAs to be evaluated. The cost in time refers to the amount of time/operation that it takes to drill the wellbore in the simulated environment.

The outputs may also or instead include a drill bit predictability. The bit predictability refers to how accurately the location of the drill bit can be predicted.

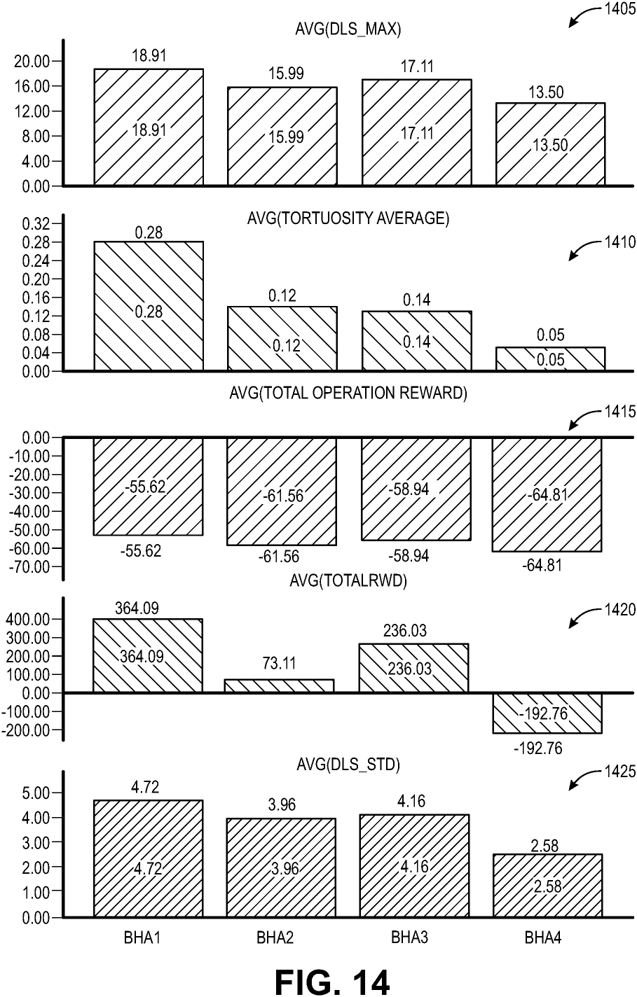

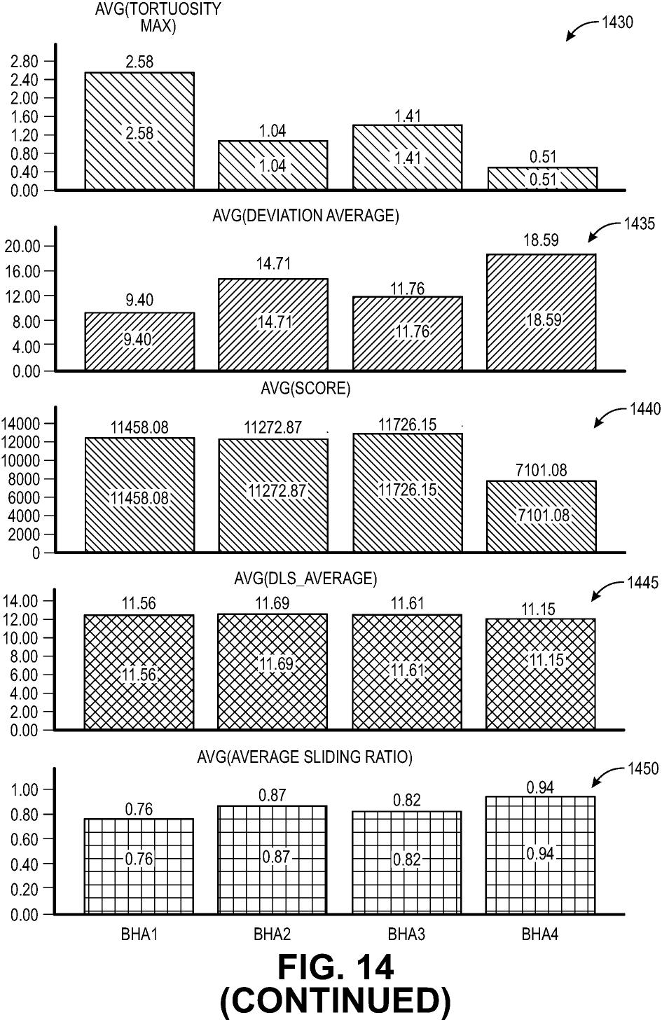

FIG. 14 illustrates the outputs of the (e.g., four) BHAs compared against one another, according to an embodiment. The graph 1405 illustrates an average of the maximum DLS for each BHA. More particularly, a plurality of simulations may be performed for each BHA. Each simulation may include a maximum DLS. The average of the maximum DLS for the first BHA is 18.91, the average of the maximum DLS for the second BHA is 15.99, the average of the maximum DLS for the third BHA is 17.11, and the average of the maximum DLS for the fourth BHA is 13.50.

The graph 1410 illustrates an average of the average tortuosity for each BHA. As mentioned above, a plurality of simulations may be performed for each BHA. Each simulation may include an average tortuosity. The average of the average tortuosity for the first BHA is 0.28, the average of the average tortuosity for the second BHA is 0.12, the average of the average tortuosity for the third BHA is 0.14, and the average of the average tortuosity for the fourth BHA is 0.05.

The graph 1415 illustrates an average of the total operation reward for each BHA. As mentioned above, a plurality of simulations may be performed for each BHA. Each simulation may include a total operation reward. The total operation reward may be based upon the operational efficiency of the BHA during the current simulation. The average of the total operation reward for the first BHA is -55.62, the average of the total operation reward for the second BHA is -61.56, the average of the total operation reward for the third BHA is -58.94, and the average of the total operation reward for the fourth BHA is -64.81.

The graph 1420 illustrates an average of the total reward for each BHA. As mentioned above, a plurality of simulations may be performed for each BHA. Each simulation may include a total reward. The total reward may be calculated while drilling and include the deviation from the plan, the operational efficiency, the drilling rewards, and the drilling to target. The average of the total reward for the first BHA is 364.09, the average of the total reward for the second BHA is 73.11, the average of the total reward for the third BHA is 236.03, and the average of the total reward for the fourth BHA is -192.76.

The graph 1425 illustrates an average of the standard deviation of the DLS for each BHA. As mentioned above, a plurality of simulations may be performed for each BHA. Each simulation may include a standard deviation of the DLS. The average of the standard deviation of the DLS for the first BHA is 4.72, the average of the standard deviation of the DLS for the second BHA is 3.96, the average of the standard deviation of the DLS for the third BHA is 4.16, and the average of the standard deviation of the DLS for the fourth BHA is 2.58.

The graph 1430 illustrates an average of the maximum tortuosity for each BHA. As mentioned above, a plurality of simulations may be performed for each BHA. Each simulation may include a maximum tortuosity. The average of the maximum tortuosity for the first BHA is 2.58, the average of the maximum tortuosity for the second BHA is 1.04, the average of the maximum tortuosity for the third BHA is 1.41, and the average of the maximum tortuosity for the fourth BHA is 0.51.

The graph 1435 illustrates an average of the average deviation for each BHA. As mentioned above, a plurality of simulations may be performed for each BHA. Each simulation may include an average deviation from the planned wellbore trajectory. The average of the average deviation for the first BHA is 9.4, the average of the average deviation for the second BHA is 14.71, the average of the average deviation for the third BHA is 11.76, and the average of the average deviation for the fourth BHA is 18.59.

The graph 1440 illustrates an average score for each BHA. As mentioned above, a plurality of simulations may be performed for each BHA. Each simulation may include an average score. The average score represents the final total reward after the simulated drilling is complete. The average score for the first BHA is 11458, the average score for the second BHA is 11273, the average score for the third BHA is 11726, and the average score for the fourth BHA is 7101.

The graph 1445 illustrates an average of the average DLS for each BHA. As mentioned above, a plurality of simulations may be performed for each BHA. Each simulation may include an average DLS. The average of the average DLS for the first BHA is 11.56, the average of the average DLS for the second BHA is 11.69, the average of the average DLS for the third BHA is 11.61, and the average of the average DLS for the fourth BHA is 11.15.

The graph 1450 illustrates an average of the average sliding ratio for each BHA. As mentioned above, a plurality of simulations may be performed for each BHA. Each simulation may include an average sliding ratio. The average of the average sliding ratio for the first BHA is 0.76, the average of the average sliding ratio for the second BHA is 0.87, the average of the average sliding ratio for the third BHA is 0.82, and the average of the average sliding ratio for the fourth BHA is 0.94.

Referring again to FIG. 8, the method 800 may also include displaying the one or more outputs, as at 808. For example, the outputs may be displayed in graphical form on a screen of a computer, a tablet, a smart phone, or the like.

The method 800 may also include selecting one of the BHAs based at least partially upon the one or more outputs, as at 810. The selection may be performed by the computing system or by a user (e.g., a directional driller). The BHA may be selected to drill the wellbore along the planned trajectory in the real (e.g., non-simulated) subterranean formation. In one embodiment, the BHA may be selected based at least partially upon the reward (e.g., graph 935 and/or graph 1820). In another embodiment, different weights may be applied to a plurality of the outputs, and the BHA may be selected based at least partially upon the weighted outputs.

The method 800 may also include causing a drilling rig to drill a wellbore using the selected BHA, as at 812. For example, the computing system may transmit a signal to the drilling rig to cause the drilling rig to drill the wellbore using the selected BHA. The wellbore may be drilled along the planned trajectory in the real (e.g., non-simulated) subterranean formation.

In some embodiments, the methods of the present disclosure may be executed by a computing system. FIG. 15 illustrates an example of such a computing system 1500, in accordance with some embodiments. The computing system 1500 may include a computer or computer system 1501A, which may be an individual computer system 1501A or an arrangement of distributed computer systems. The computer system 1501A includes one or more analysis modules 1502 that are configured to perform various tasks according to some embodiments, such as one or more methods disclosed herein. To perform these various tasks, the analysis module 1502 executes independently, or in coordination with, one or more processors 1504, which is (or are) connected to one or more storage media 1506. The processor(s) 1504 is (or are) also connected to a network interface 1507 to allow the computer system 1501A to communicate over a data network 1509 with one or more additional computer systems and/or computing systems, such as 1501B, 1501C, and/or 1501D (note that computer systems 1501B, 1501C and/or 1501D may or may not share the same architecture as computer system 1501A, and may be located in different physical locations, e.g., computer systems 1501A and 1501B may be located in a processing facility, while in communication with one or more computer systems such as 1501C and/or 1501D that are located in one or more data centers, and/or located in varying countries on different continents).

A processor may include a microprocessor, microcontroller, processor module or subsystem, programmable integrated circuit, programmable gate array, or another control or computing device.

The storage media 1506 may be implemented as one or more computer-readable or machine-readable storage media. Note that while in the example embodiment of FIG. 15 storage media 1506 is depicted as within computer system 1501A, in some embodiments, storage media 1506 may be distributed within and/or across multiple internal and/or external enclosures of computing system 1501A and/or additional computing systems. Storage media 1506 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 1500 contains one or more BHA evaluation module(s) 1508. In the example of computing system 1500, computer system 1501A includes the BHA evaluation module 1508. In some embodiments, a single BHA evaluation module may be used to perform some aspects of one or more embodiments of the methods disclosed herein. In other embodiments, a plurality of BHA evaluation modules may be used to perform some aspects of methods herein.

It should be appreciated that computing system 1500 is merely one example of a computing system, and that computing system 1500 may have more or fewer components than shown, may combine additional components not depicted in the example embodiment of FIG. 15, and/or computing system 1500 may have a different configuration or arrangement of the components depicted in FIG. 15. The various components shown in FIG. 15 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 1500, FIG. 15), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrate and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for evaluating one or more bottom hole assemblies (BHAs), the method comprising:
receiving a plurality of inputs comprising:
one or more properties of the one or more BHAs;
a planned trajectory of a wellbore; and
one or more properties of a subterranean formation into which the wellbore will be drilled;
simulating drilling the wellbore in the subterranean formation based at least partially upon the inputs, wherein drilling of the wellbore is simulated with one or more artificial intelligence (AI) agents, wherein drilling of the wellbore is simulated a plurality of times using each of the one or more BHAs, thereby producing a plurality of simulations, and wherein each simulation is generated using a different one of the AI agents; and
generating one or more outputs in response to simulating drilling the wellbore.

2. The method of claim 1, wherein the plurality of simulations comprises a first simulation and a second simulation, wherein the one or more properties of the one or more BHA and the planned trajectory of the wellbore remain the same for the first and second simulations.

3. The method of claim 2, wherein the one or more properties of the subterranean formation are different for the first and second simulations.

4. The method of claim 1, wherein the one or more outputs comprise a reward for each of the simulations, and wherein the reward is determined based at least partially upon a deviation of a simulated trajectory from the planned trajectory.

5. The method of claim 1, wherein the one or more outputs comprise a simulated trajectory of the wellbore for each of the simulations and a deviation of the simulated trajectory from the planned trajectory for each of the simulations.

6. The method of claim 1, wherein the one or more outputs comprise a tortuosity of a simulated trajectory of the wellbore for each of the simulations, a dog-leg severity (DLS) for each of the simulations, or both.

7. The method of claim 1, wherein the one or more outputs comprise a success rate for each of the BHAs.

8. The method of claim 1, further comprising displaying the one or more outputs.

9. The method of claim 1, further comprising selecting one of the one or more BHAs based at least partially upon the one or more outputs.

10. The method of claim 9, further comprising causing a drilling rig to drill the wellbore in the subterranean formation using the selected BHA.

11. A non-transitory computer-readable medium storing instructions that, when executed by at least one processor of a computing system, cause the computing system to perform operations, the operations comprising:
receiving a plurality of inputs comprising:
one or more properties of a plurality of bottom hole assemblies (BHAs), wherein the one or more properties comprise a size of a drill bit of the BHAs, a size of a motor of
the BHAs, an amount of bend in the BHAs, or a combination thereof;
a planned trajectory of a wellbore; and
one or more properties of a subterranean formation into which the wellbore will be drilled;
simulating drilling the wellbore in the subterranean formation based at least partially upon the inputs, wherein drilling of the wellbore is simulated with one or more artificial intelligence (AI) agents, wherein drilling of the wellbore is simulated a plurality of times using each of the BHAs, thereby producing at least a first simulation and a second simulation for each BHA, and wherein the one or more properties of the subterranean formation are different for the first and second simulations;
generating a plurality of outputs in response to simulating drilling the wellbore, wherein a first of the outputs comprises a reward.

12. The non-transitory computer-readable medium of claim 11, wherein the plurality of outputs also comprises a second output and a third output, wherein the reward is based at least partially upon a deviation of the second and third outputs from planned values.

13. The non-transitory computer-readable medium of claim 12, wherein reward comprises an average of an average value for each of the simulations.

14. The non-transitory computer-readable medium of claim 12, wherein reward comprises an average of a maximum value for each of the simulations.

15. The non-transitory computer-readable medium of claim 11, wherein the operations further comprise:
selecting one of the BHAs based at least partially upon the outputs; and
transmitting a signal to cause a drilling rig to drill the wellbore in the subterranean formation using the selected BHA.

16. A computing system, comprising:
one or more processors; and
a memory system including one or more non-transitory computer-readable media storing instructions that, when executed by at least one of the one or more processors, cause the computing system to perform operations, the operations comprising:
receiving a plurality of inputs comprising:
one or more properties of a plurality of bottom hole assemblies (BHAs), wherein the one or more properties comprise a size of a drill bit of the BHAs, a size of a motor of the BHAs, an amount of bend in the BHAs, or a combination thereof;
a planned trajectory of a wellbore; and
one or more properties of a subterranean formation into which the wellbore will be drilled;
simulating drilling the wellbore in the subterranean formation based at least partially upon the inputs, wherein drilling of the wellbore is simulated with one or more artificial intelligence (AI) agents, wherein drilling of the wellbore is simulated a plurality of times using each of the BHAs, thereby producing at least a first simulation and a second simulation for each BHA, wherein the one or more properties of the BHAs and the planned trajectory of the wellbore remain the same for the first and second simulations, and wherein the one or more properties of the subterranean formation are different for the first and second simulations;
generating a plurality of outputs in response to simulating drilling the wellbore, wherein the plurality of outputs comprises:
a direction of a tool face of the BHAs for each of the simulations;
a simulated trajectory of the wellbore for each of the simulations;
a tortuosity of the simulated trajectory for each of the simulations;
a dog-leg severity (DLS) for each of the simulations;
a reward for each of the simulations; and
a success rate for each of the BHAs;
selecting one of the BHAs based at least partially upon the one or more outputs; and
causing a drilling rig to drill the wellbore in the subterranean formation using the selected BHA.

17. The computing system of claim 16, wherein the reward is based at least partially upon deviations of the direction of the tool face, the simulated trajectory of the wellbore, the tortuosity of the simulated trajectory, and the DLS from planned values.

18. The computing system of claim 16, wherein the outputs also comprise a deviation of the simulated trajectory from the planned trajectory, and wherein the deviation is measured in degrees and distance.

19. The computing system of claim 16, wherein the DLS is measured for the subterranean formation and the simulated trajectory.

20. The computing system of claim 16, further comprising assigning different weights to each of the outputs.
